(19) United States
(12) Patent Application Publication
(10) Pub. No.: US 2026/0063688 A1
(43) Pub. Date: Mar. 5, 2026

(54) DOMAIN-ADAPTED MULTIMODAL LARGE LANGUAGE MODELS BASED ON TENSOR BUILD FOR CALIBRATION AND MEASUREMENT

(71) Applicant: Tektronix, Inc., Beaverton, OR (US)

(72) Inventors: Kan Tan, Portland, OR (US); John J. Pickerd, Hillsboro, OR (US)

(21) Appl. No.: 19/308,095

(22) Filed: Aug. 22, 2025

Related U.S. Application Data
(60) Provisional application No. 63/688,166, filed on Aug. 28, 2024.

(51) Int. Cl. G01R 19/25; G01R 19/252

(52) U.S. Cl. CPC G01R 19/2509; G01R 19/252

(57) ABSTRACT

A test and measurement instrument includes a port to allow the test and measurement instrument to connect to a device under test (DUT) to receive signals from the DUT, one or more analog-to-digital converters (ADCs) to receive a signal from the DUT and convert the signal to one or more digital waveforms, a user interface to allow a user to enter a query, and one or more processors configured to execute code that causes the one or more processors to: build one or more images of the one or more digital waveforms from the one or more ADCs, send the one or more images to a domain-adapted multimodal large language model (MLLM), receive parameters from the domain-adapted MLLM, provide the user with parameters for the DUT in response to the query, and apply the parameters to the DUT.

### CROSS-REFERENCE TO RELATED APPLICATIONS

This disclosure is a non-provisional of and claims benefit from U.S. Provisional Application No. 63/688,166, titled “DOMAIN-ADAPTED MULTIMODAL LARGE LANGUAGE MODELS BASED ON TENSOR BUILD FOR CALIBRATION AND MEASUREMENT,” filed on Aug. 28, 2024, the disclosure of which is incorporated herein by reference in its entirety.

### TECHNICAL FIELD

This disclosure relates to test and measurement systems, and more particularly to test and measurement systems employing machine learning (ML) for calibrating and/or measuring a device under test (DUT).

### BACKGROUND

Communication systems generally include transmitters and receivers. When the signal speed increases, more complex equalizers in transmitters and receivers are used to improve the system performance. The tuning of the transmitter and the adaptation of receiver equalizers involves more optimization, and the system performance measurement involves more computation. U.S. Pat. App. Pub. No. 20220373598, published Nov. 24, 2022, titled “SHORT PATTERN WAVEFORM DATABASE BASED MACHINE LEARNING FOR MEASUREMENT,” hereinafter “the '598 publication,” the contents of which are hereby incorporated by reference herein in its entirety, discloses a short pattern waveform tensor builder-based machine learning (ML) system, which can be used for, among other things, tuning and measurement of a device under test (DUT), such as a transmitter, for example. The short pattern waveform tensor builder-based ML system is designed to improve the measurement speed by using short pattern waveform tensors as the feature representation of the long waveform acquired from the DUT, then performing transfer learning to get the map from the 2-D tensor image to the measurement result.

The short pattern waveform tensor-based ML system has been expanded to cover other wired and wireless communication applications. For example, U.S. patent application Ser. No. 18/754,871, filed Jun. 26, 2024, titled “MULTIPLE PULSE EXTRACTION FOR TRANSMITTER CALIBRATION,” hereinafter “the '871 application,” the contents of which are hereby incorporated by reference in its entirety herein, discloses techniques for extracting multiple linear fit pulse responses from a waveform. For example, the multiple linear fit pulse responses (MLFPR) are extracted from PAM4 waveforms as shown in FIG. 1 and FIG. 2.

As disclosed in U.S. Pat. App. Pub. No. 20240169210, published May 23, 2024, titled “METHODS FOR 3D TENSOR BUILDER FOR INPUT TO MACHINE LEARNING,” hereinafter “the '210 publication,” the contents of which are hereby incorporated by reference herein in its entirety, the extracted pulses and the vertical noise histogram can be built into a 3-D tensor. In the 3-D tensor the intensity of the pixels represents the amplitude of the samples in the pulses or the hits of the vertical histogram. The 3-D tensor is represented in an image, an example of which is shown in FIG. 3. In this particular example, in the gray lines at the bottom such as 14, the darker colors represent high amplitude of a linear fit pulse. Line 12 at the top represents a histogram of the number of hits for the waveform represented by this tensor image. Current architectures use a convolutional neural network (CNN), such as that shown in FIG. 4, with the image from FIG. 3 as an input to the model. The CNN has an input layer 20, hidden layers such as 22 and an output layer 24.

This approach uses transfer learning since pre-trained CNN models such as Resnet have the capability to extract features from the image. The transfer learning process adapts the fully connected layer and the output layer to make the accurate map from an input data image to the corresponding label to produce the measurement result. This example of an ML system has been adapted to handle calibration and characterization applications.

However, there is a limitation in this ML system. For the same waveforms, if a different measurement, calibration, or characterization parameter is required, the ML model needs to be re-trained, or a separate ML model needs to be built.

### BRIEF DESCRIPTION OF THE DRAWINGS

FIG. 1 shows an example of a pulse amplitude modulation-4 (PAM4) waveform.

FIG. 2 shows an example of four linear fit pulse responses from a PAM4 waveform.

FIG. 3 shows an example of an image representing a 3-D tensor.

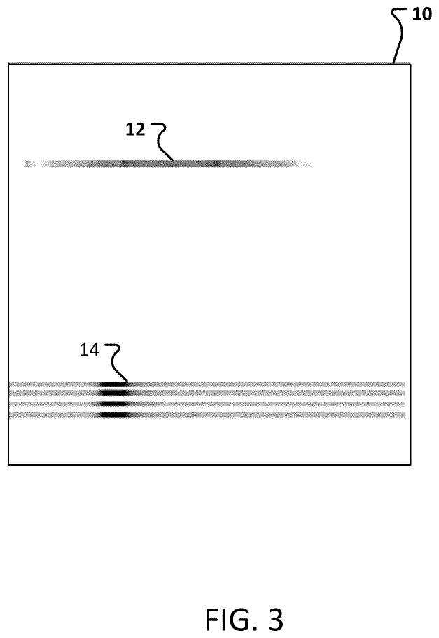

FIG. 4 shows an embodiment of a convolutional neural network architecture.

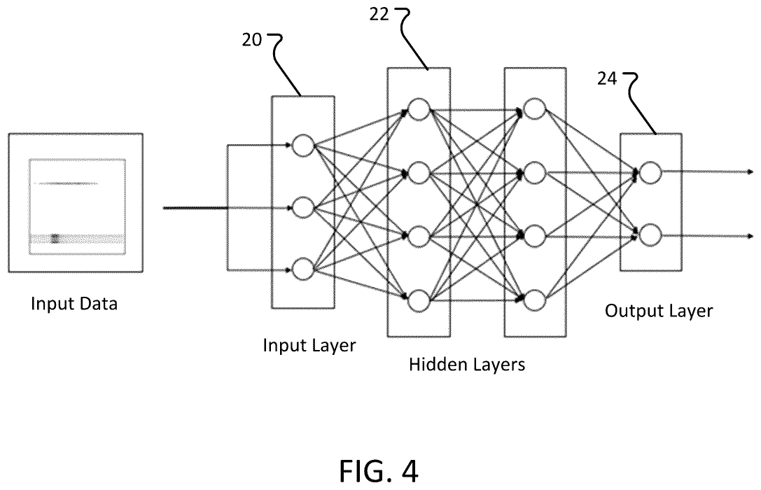

FIG. 5 shows an embodiment of a test and measurement instrument.

FIG. 6 shows an example of a current machine learning system.

FIG. 7 shows an embodiment of a multimodal large language model (MLLM) for calibration, characterization, and measurement undergoing training.

FIG. 8 shows an embodiment of a MLLM model in use.

### DETAILED DESCRIPTION

The embodiments here involve a new system and method that uses short pattern waveform tensors and their derivatives, all of which generate images. The embodiments use text to represent measurement, calibration, and characterization parameters.

The text-based large language model (LLM) has a large amount of knowledge, for example, it can summarize a long novel. The LLM understands that the short summary of the novel and the full-length novel are highly correlated. Besides a summary, the pre-trained LLM has other understandings of the novel without additional training. Further development from LLMs has resulted in multimodal large language models. The term “multimodal large language model” (MLLM) as used here means a model that merges the capabilities of large language models, such as Chat-GPT, with other modalities in addition to text, such as audio, video, and images. Examples of these include CLIP (Contrastive Language-Image Pretraining), which is a vision-language model.

The embodiments perform domain adaptation upon a multimodal large language model (MLLM) that has undergone pre-training on publicly available information, prior to adaptation. With additional domain-specific training, the embodiments create a domain-adapted foundation model for measurement, calibration, and characterization.

Currently available MLLMs contain a huge amount of knowledge in several modalities. Domain adaption allows the MLLM to adapt to the special domain in addition to its pre-training with the general available public data. The domain-adapted MLLM has more intelligence and can generate more accurate results. This domain-adapted MLLM can be deployed in test and measurement environments, either as a local MLLM on a test and measurement instrument or located where the test and measurement instrument can access it.

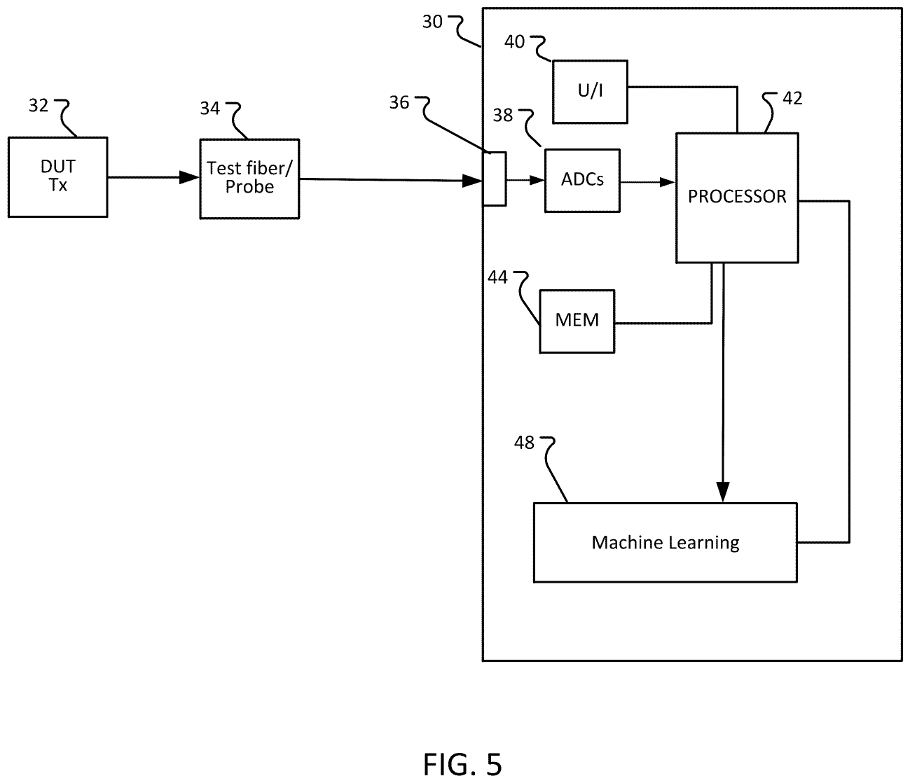

FIG. 5 shows an embodiment of a test and measurement instrument 30. A device under test (DUT) 32 generates a waveform that a test and measurement instrument captures. The testing setup may include a test and measurement instrument such as an oscilloscope 30. The test and measurement instrument 30 receives a signal from DUT 32 directly or through an instrument probe 34. In the case of an optical transmitter DUT, the probe will typically comprise a test fiber coupled to an optical to electrical converter, not shown, that provides a signal to the test and measurement instrument through one or more ports 36. Two ports may be used for differential signaling, while one port is used for single-ended signaling. The signals are sampled and digitized by one or more analog-to-digital converters (ADCs) 38 to become digital waveforms.

The test and measurement instrument has one or more processors represented by processor 42, a memory 44 and a user interface 40. The memory may store executable instructions in the form of code that, when executed by the processor, causes the processor to perform tasks. User interface 40 of the test and measurement instrument allows a user to interact with instrument 30, such as to input settings, configure tests, make queries, which will be discussed in more detail later, etc.

The embodiments here employ machine learning in the form of machine learning system 48. The machine learning network may include a processor that has been programmed with the MLLM as either part of the test and measurement instrument, or to which the test and measurement instrument has access. As test equipment capabilities and processors evolve, the one or more processors such as 42 may include both. The machine learning system may take the form of programmed models operating on one or more of the processors.

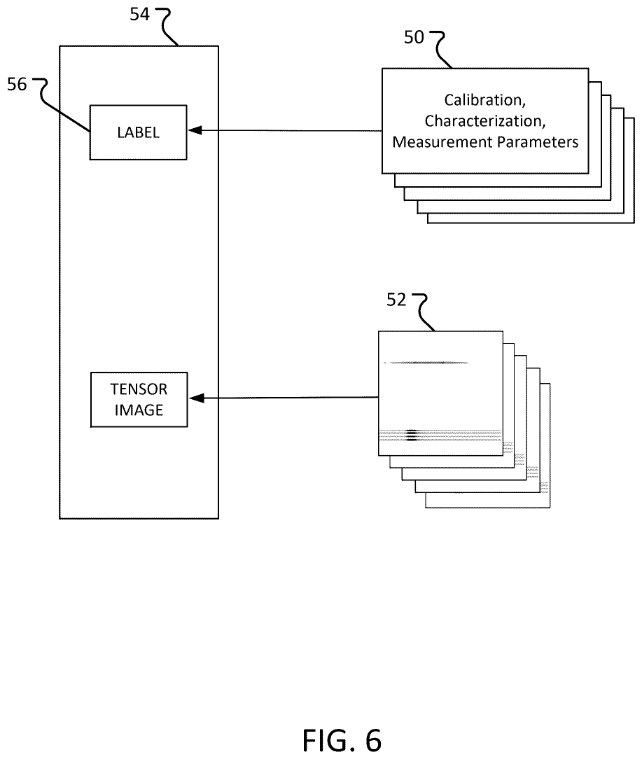

In current ML systems, such as that shown in FIG. 6, ML network 54 is trained on tensor images 52 for which the calibration, characterization, and measurement parameters have a label that is a simple vector 56. This results in an effective ML system for a particular set of circumstances. For example, one ML model may have undergone training to output the tap values for an optimal feed forward equalizer (FFE) with 5 taps. If the user wants the tap values for a FFE having 9 taps, either the current model needs to undergo new training, or the user has to build a separate ML system because for the current ML models 5 taps and 9 taps are completely different. The determination of the FFE taps could comprise either a measurement defined by a text specification, such as the IEEE 800G/800G Ethernet standard, or characterization of the taps.

The embodiments herein now provide the machine learning system 48 as a domain-adapted MLLM. In the above example, if the domain-adapted MLLM has undergone training to produce a 5-tap FFE, the domain-adapted MLLM can understand that the 5-tap and the 9-tap FFEs have encoded vectors close to one another, in terms of cosine distance. The domain-adapted MLLM can then “reason”and produce the values for a 9-tap FFE.

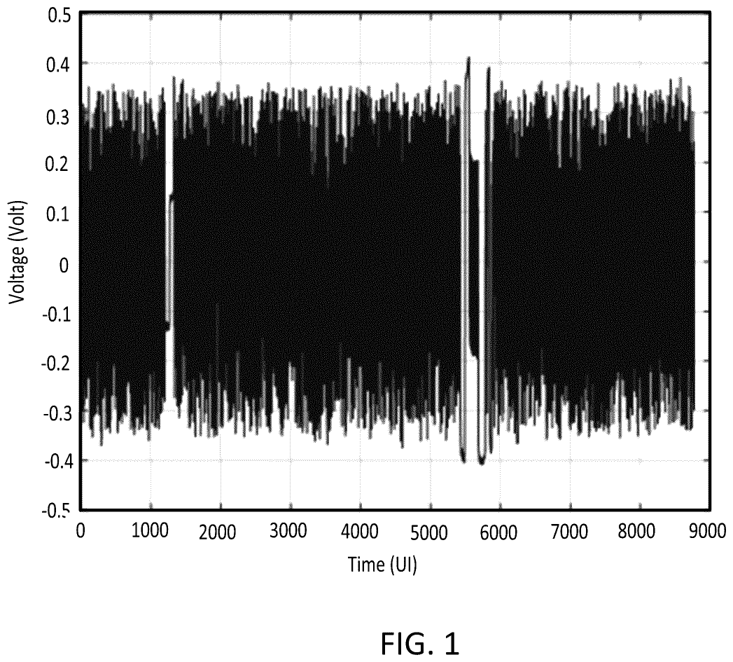

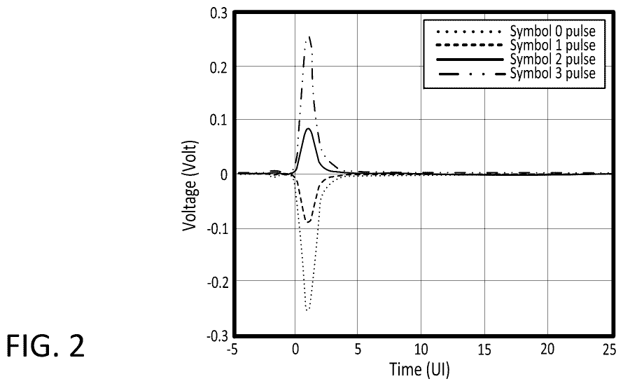

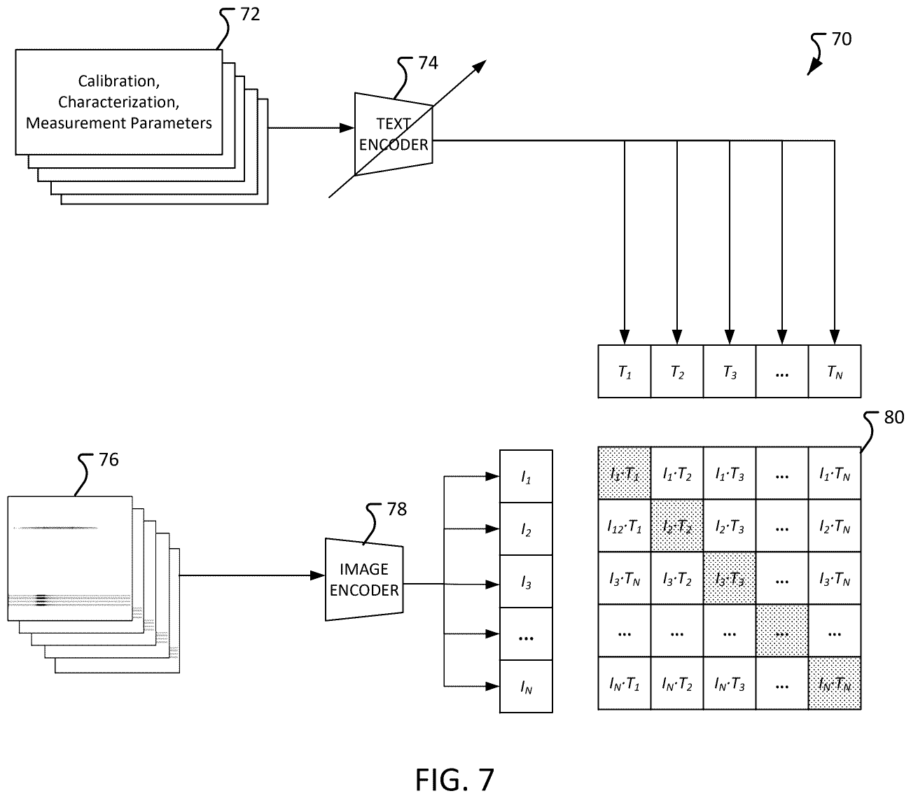

FIG. 7 shows an embodiment of a domain-adapted MLLM as it undergoes training. The training process involves providing the domain-adapted MLLM with the domain specific training. The training process, according to some embodiments of the disclosure, begins with feature extraction. The features of the waveforms are extracted and represented as images 76 in a manner similar to the current machine learning implementations such as in FIG. 6. For example, the pulses are extracted and are represented in the image as shown in FIG. 2 for the PAM4 signal shown in FIG. 1.

These images are then used in preparing the domain specific training data set. The images represent the features of the data set, and calibration, characterization and measurement parameters are represented in text 72. Each image has a corresponding text entry.

The pre-trained MLLM, such as CLIP, is refined using the domain specific data set by adapting the text encoder 74 to align with the image encoder 78. The alignment between the text modality model and image modality model is measured. In one embodiment, the measurement of the alignment of two vectors may use cosine distance. In cosine distance, a−1 means that the vectors are pointing in opposite directions, so aligned vectors will have a measure very close or equal to 1. In matrix 80, the center values with the image and text align are patterned. The alignment of the vectors results in these intersections have high values.

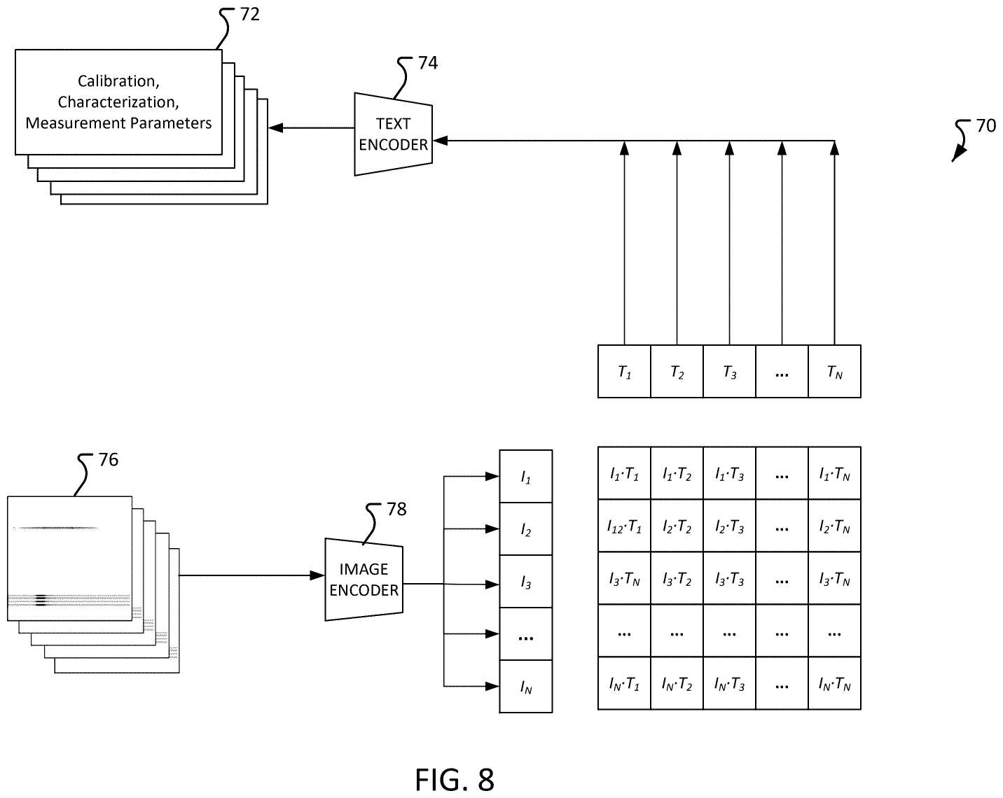

After the model refinement is completed, the domain-adapted MLLM can be used in runtime to generate results based on the input image or images 76 through the image encoder 78. This usually occurs with the query as shown in FIG. 8. The domain-adapted MLLM can take in the image representing features as input and generate calibration, characterization and measurement parameters based on a user query about the DUT received through the user interface of the test and measurement instrument. In this situation, the text comprises an output, not an input, so the arrows go in the other direction.

The text decoder outputs text result based on the text vector that equals the vector encoded from the image input and the query text. The query text tells the type of calibration, characterization, and measurement parameters. The text encoder 74 will translate or decode the text vector from the domain adapted MLLM to produce the parameters for the DUT.

Depending upon the nature of the parameters, applying the parameters to the DUT may take different forms. For example, the parameters may comprise characterization parameters, indicating characteristics of the DUT. The characterization of the DUT may be compared against the design specification to see if the design meets the requirements and whether further design change is needed during the design phase. The characterization may also comprise information provided in the tuning process as part of the tensor image during the tuning process. When the parameters comprise calibration parameters, the instrument may adjust the settings or other operating parameters on the DUT to match the values of the calibration parameters. When the parameters comprise measurements of the DUT, those measurements may be compared to a test specification, rather than a design specification although they may be the same or similar, to determine if the DUT has passed or failed the test, meaning that the DUT does or does not comply with the specification. These just provide some examples and are not intended to limit the embodiments or scope of the claims.

The embodiments herein expand the machine learning (ML) applications for calibration, characterization, and measurement to a domain-adapted MLLM. The text modality model in MLLM has a large amount of knowledge and intelligence, has better capability to understand the meaning of the calibration, characterization, and measurement parameters. This makes the domain-adapted MLLM capable of handling a variety of applications without having to train multiple different models in an ML approach. The domain-adapted MLLM has more intelligence and can generate more accurate results.

Aspects of the disclosure may operate on a particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### EXAMPLES

Illustrative examples of the disclosed technologies are provided below. An embodiment of the technologies may include one or more, and any combination of, the examples described below.

Example 1 is test and measurement instrument, comprising: a port to allow the test and measurement instrument to connect to a device under test (DUT) to receive signals from the DUT; one or more analog-to-digital converters (ADCs) to receive a signal from the DUT and convert the signal to one or more digital waveforms; a user interface to allow a user to enter a query; and one or more processors configured to execute code that causes the one or more processors to: build one or more images of the one or more digital waveforms from the one or more ADCs; send the one or more images to a domain-adapted multimodal large language model (MLLM); receive parameters from the domain-adapted MLLM; provide the user with parameters for the DUT in response to the query; and apply the parameters to the DUT.

Example 2 is the test and measurement instrument of Example 1, wherein the MLLM resides in the test and measurement instrument.

Example 3 is the test and measurement instrument of either Examples 1 or 2, wherein the MLLM resides remotely from the test and measurement instrument.

Example 4 is the test and measurement instrument of any of Examples 1 through 3, wherein the images comprise one of three-dimensional tensors or two-dimensional tensors.

Example 5 is the test and measurement instrument of any of Examples 1 through 4, wherein the one or more processors are further configured to execute code to train a multi-modal large language model (MLLM) to create the domain-adapted MLLM.

Example 6 is the test and measurement instrument of Example 5, wherein the code that causes the one or more processors to train the MLLM comprises code that causes the one or more processors to upload one or more training data sets, the data sets comprising images of features extracted from waveforms and corresponding text representing at least one of calibration, characterization, and measurement parameters of the waveforms.

Example 7 is the test and measurement instrument of any of Examples 1 through 6, wherein the parameters received are characterization parameters of the DUT and the code that causes the one or more processors to apply the parameters to the DUT comprises code that causes the one or more processors to compare the characterization parameters of the DUT with a design specification to determine if the design meet the design requirements.

Example 8 is the test and measurement instrument of Example 7, wherein the code that causes the one or processors to compare the characterization parameters of the DUT comprises code that causes the one or more processors to determine whether further design change is needed during a design phase.

Example 9 is the test and measurement instrument of any of Examples 1 through 8, wherein the parameters received are measurement parameters of the DUT and the code that causes the one or more processors to apply the parameters to the DUT comprises code to compare the measurement parameters with a specification to determine if the DUT has passed or failed.

Example 10 is the test and measurement instrument of any of Examples 1 through 9, wherein the parameters comprise calibration parameters and the code that causes the one or more processors to apply the parameters to the DUT comprises code to set parameters on the DUT to values of the calibration parameters.

Example 11 is a method, comprising: receiving a query from a user through a user interface of a test and measurement instrument connected to a device under test (DUT); receiving one or more digital waveforms from one or more analog-to-digital controllers (ADCs) in the test and measurement instrument; building one or more images of the one or more digital waveforms; sending the one or more images to a domain-adapted multimodal large language model (MLLM); receiving parameters from the domain-adapted MLLM; providing the user with parameters for the DUT in response to the query; and applying the parameters to the DUT.

Example 12 is the method of Example 11, wherein sending the one or more images to the domain-adapted MLLM comprises sending the one or more images to the domain-adapted MLLM on the test and measurement instrument.

Example 13 is the method of either Example 11 or 12, wherein sending the one or more images to the domain-adapted MLLM comprises sending the one or more images to the domain-adapted MLLM remote from the test and measurement instrument.

Example 14 is the method of any of Examples 11 through 13, wherein the images comprise one of three-dimensional tensors or two-dimensional tensors.

Example 15 is the method of any of Examples 11 through 14, further comprising training a multimodal large language model (MLLM) to create the domain-adapted MLLM.

Example 16 is the method of Example 15, wherein training the MLLM comprises: perform feature extraction on a set of waveforms to produce a set of features; build a set of images representing the features; create one or more training data sets comprises of the set of images and corresponding text for each image, the text comprising at least one of calibration, characterization, and measurement parameters; and upload the one or more training data sets to the MLLM to create the domain-adapted MLLM.

Example 17 is the method of any of Examples 11 through 16, wherein the parameters comprise characterization parameters and applying the parameters to the DUT comprises comparing the characterization parameters to a design specification to determine if the design meets the design requirements.

Example 18 is the method of Example 17, further comprising determining whether further design change is needed.

Example 19 is the method of any of Examples 11 through 18, wherein the parameters comprise measurement parameters and applying the parameters to the DUT comprises comparing the measurement parameters to a test specification and determining whether the DUT as passed or failed.

Example 20 is the method of any of Examples 11 through 19, wherein the parameters comprise calibration parameters and applying the parameters to the DUT comprises setting parameters on the DUT to values of the calibration parameters.

All features disclosed in the specification, including the claims, abstract, and drawings, and all the steps in any method or process disclosed, may be combined in any combination, except combinations where at least some of such features and/or steps are mutually exclusive.

Each feature disclosed in the specification, including the claims, abstract, and drawings, can be replaced by alternative features serving the same, equivalent, or similar purpose, unless expressly stated otherwise.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
a port to allow the test and measurement instrument to connect to a device under test (DUT) to receive signals from the DUT;
one or more analog-to-digital converters (ADCs) to receive a signal from the DUT and convert the signal to one or more digital waveforms;
a user interface to allow a user to enter a query; and
one or more processors configured to execute code that causes the one or more processors to:
build one or more images of the one or more digital waveforms from the one or more ADCs;
send the one or more images to a domain-adapted multimodal large language model (MLLM);
receive parameters from the domain-adapted MLLM;
provide the user with parameters for the DUT in response to the query; and
apply the parameters to the DUT.

2. The test and measurement instrument as claimed in claim 1, wherein the MLLM resides in the test and measurement instrument.

3. The test and measurement instrument as claimed in claim 1, wherein the MLLM resides remotely from the test and measurement instrument.

4. The test and measurement instrument as claimed in claim 1, wherein the images comprise one of three-dimensional tensors or two-dimensional tensors.

5. The test and measurement instrument as claimed in claim 1, wherein the one or more processors are further configured to execute code to train a multi-modal large language model (MLLM) to create the domain-adapted MLLM.

6. The test and measurement instrument as claimed in claim 5, wherein the code that causes the one or more processors to train the MLLM comprises code that causes the one or more processors to upload one or more training data sets, the data sets comprising images of features extracted from waveforms and corresponding text representing at least one of calibration, characterization, and measurement parameters of the waveforms.

7. The test and measurement instrument as claimed in claim 1, wherein the parameters received are characterization parameters of the DUT and the code that causes the one or more processors to apply the parameters to the DUT comprises code that causes the one or more processors to compare the characterization parameters of the DUT with a design specification to determine if the design meet the design requirements.

8. The test and measurement instrument as claimed in claim 7, wherein the code that causes the one or processors to compare the characterization parameters of the DUT comprises code that causes the one or more processors to determine whether further design change is needed during a design phase.

9. The test and measurement instrument as claimed in claim 1, wherein the parameters received are measurement parameters of the DUT and the code that causes the one or more processors to apply the parameters to the DUT comprises code to compare the measurement parameters with a specification to determine if the DUT has passed or failed.

10. The test and measurement instrument as claimed in claim 1, wherein the parameters comprise calibration parameters and the code that causes the one or more processors to apply the parameters to the DUT comprises code to set parameters on the DUT to values of the calibration parameters.

11. A method, comprising:
receiving a query from a user through a user interface of a test and measurement instrument connected to a device under test (DUT);
receiving one or more digital waveforms from one or more analog-to-digital controllers (ADCs) in the test and measurement instrument;
building one or more images of the one or more digital waveforms;
sending the one or more images to a domain-adapted multimodal large language model (MLLM);
receiving parameters from the domain-adapted MLLM;
providing the user with parameters for the DUT in response to the query; and
applying the parameters to the DUT.

12. The method as claimed in claim 11, wherein sending the one or more images to the domain-adapted MLLM comprises sending the one or more images to the domain-adapted MLLM on the test and measurement instrument.

13. The method as claimed in claim 11, wherein sending the one or more images to the domain-adapted MLLM comprises sending the one or more images to the domain-adapted MLLM remote from the test and measurement instrument.

14. The method as claimed in claim 11, wherein the images comprise one of three-dimensional tensors or two-dimensional tensors.

15. The method as claimed in claim 11, further comprising training a multimodal large language model (MLLM) to create the domain-adapted MLLM.

16. The method as claimed in claim 15, wherein training the MLLM comprises:
perform feature extraction on a set of waveforms to produce a set of features;
build a set of images representing the features;
create one or more training data sets comprises of the set of images and corresponding text for each image, the text comprising at least one of calibration, characterization, and measurement parameters; and
upload the one or more training data sets to the MLLM to create the domain-adapted MLLM.

17. The method as claimed in claim 11, wherein the parameters comprise characterization parameters and applying the parameters to the DUT comprises comparing the characterization parameters to a design specification to determine if the design meets the design requirements.

18. The method as claimed in claim 17, further comprising determining whether further design change is needed.

19. The method as claimed in claim 11, wherein the parameters comprise measurement parameters and applying the parameters to the DUT comprises comparing the measurement parameters to a test specification and determining whether the DUT as passed or failed.

20. The method as claimed in claim 11, wherein the parameters comprise calibration parameters and applying the parameters to the DUT comprises setting parameters on the DUT to values of the calibration parameters.
